(19) United States
(12) Patent Application Publication
(10) Pub. No.: US 2023/0399767 A1
(43) Pub. Date: Dec. 14, 2023

(54) SYSTEMS AND METHODS FOR PULSED BEAM DEPOSITION OF EPITAXIAL CRYSTAL LAYERS

(71) Applicant: Paul COLOMBO, Minnetonka Beach, MN (US)

(72) Inventor: Paul COLOMBO, Minnetonka Beach, MN (US)

(21) Appl. No.: 18/201,023

(22) Filed: May 23, 2023

Related U.S. Application Data
(60) Provisional application No. 63/351,446, filed on Jun. 13, 2022.

(51) Int. Cl. C30B 23/02; C30B 29/02

(52) U.S. Cl. CPC C30B 23/025; C30B 29/02

(57) ABSTRACT

The present invention provides a Pulsed Beam Deposition (PBD) architecture that aims effusion cells parallel to the axis of rotation and off-center of an annular-shaped substrate holder. This configuration results in pulsed, single elemental substrate exposure and no co-deposition when multiple sources are open. Migration-enhanced epitaxy (MEE) is achieved automatically with no sequential shuttering. PBD with built-in MEE solves both shutter fatigue and growth-rate limitations of traditional MEE. Some embodiments provide a PBD apparatus comprising a plurality of elemental effusion cells positioned to deposit elemental materials onto a revolving substrate held by a rotatable substrate holder, wherein the rotatable substrate holder and the plurality of elemental effusion cells are configured to limit direct exposure at any point on the substrate to a maximum of one elemental effusion cell at a time. Methods of using the PBD apparatus, and epitaxial wafers that may be fabricated with the PBD apparatus, are disclosed.

### PRIORITY DATA

This patent application claims priority to U.S. Provisional Patent App. No. 63/351,446, filed on Jun. 13, 2022, which is hereby incorporated by reference.

### FIELD OF THE INVENTION

The present invention generally relates to improved apparatus and methods for molecular beam epitaxy and migration-enhanced epitaxy.

### BACKGROUND OF THE INVENTION

Molecular beam epitaxy (“MBE”) is a physical vapor deposition method for epitaxially growing a thin layer on a substrate useful for the production of compound semiconductors, particularly group III-group V compound semiconductors. MBE is widely used in the manufacture of many types of semiconductor devices. In MBE, elements are emitted in the form of molecular or atomic beams (e.g., As₂ or As₄ in the case of arsenic) under a ultra-high vacuum (e.g. 10⁻¹¹ Torr) and deposited on a monocrystal substrate (e.g. GaAs or InP). The absence of carrier gases, as well as ultra-high vacuum, result in extremely high purity of the epitaxially grown films. An important aspect of MBE is the deposition rate—typically less than about 1 micron per hour—that allows films to grow epitaxially.

MBE is known to have various advantages. There is superior layer control compared to other techniques; almost any fraction of an atomic layer may be deposited, and layers may be sequenced one layer at a time (for example, Ga then As then Ga, etc.). Due to the use of a ultra-high vacuum, gaseous impurities are expelled, which improves the product quality. A uniform layer may be deposited over a large area. It is possible to precisely control the film thickness in angstroms because the crystal growth rate can be accurately controlled. It is possible to obtain a thin film of multi-component mixed crystals by simply increasing molecular beam sources.

In solid-source MBE, elements such as gallium and arsenic, in ultra-pure form, are heated in separate Knudsen effusion cells or electron-beam evaporators until the elements begin to evaporate or sublime to the vapor phase. The flux of vapor atoms is controlled by the temperature of the effusion cell. Shutters are used to turn the beam flux on and off. When beam flux is turned on, vapor elements will diffuse to and condense on the substrate, where reactions may occur. Controlling the temperature of the source controls the rate of material impinging the substrate surface, and the temperature of the substrate influences the rate of hopping or desorption from the surface. Because of the very low pressure in MBE, the mean free path of the atoms is long (e.g., hundreds of meters). The vapor-phase atoms thus travel in a straight line (a beam) toward a substrate, via Knudsen diffusion, and thus do not interact with each other or with vacuum chamber impurities or walls. Once on the substrate, an atom or molecule moves around until a chemical bond is formed with another atom.

In gas-source MBE, which may be referred to as “GSMBE”, one or more beams are derived from a gas source. One example of GSMBE is hydride MBE, in which materials such as arsenic and phosphorus are derived from cracked AsH₃ and PH₃, respectively, at the source end and delivered to the substrate as elemental polyatomic or monoatomic beams. One type of GSMBE for epitaxial growth under ultrahigh vacuum is chemical beam epitaxy (“CBE”). In CBE, the reactants are in the form of molecular beams of reactive gases, typically as a hydride or as a metal-organic species. In metal-organic MBE (“MOMBE”), which is another type of GSMBE, one component is obtained from a gaseous source while another component is obtained from a solid source. The background pressure in GSMBE is higher than in conventional MBE, due to the presence of gases such as Hz. It is important to emphasize that although the background pressure can be orders of magnitude higher in GSMBE compared to MBE, the material is still delivered to the substrate as collisionless kinematic beams rather than as viscous flow as in higher-pressure CVD systems. The utilization of collisionless beams (long mean free paths) is a common feature of traditional MBE as well as GSMBE.

Prior-art MBE architecture aims effusion cells at an angle relative to the substrate and on or near the center of a disk-shaped substrate holder, resulting in multi-elemental substrate exposure and co-deposition when multiple effusion cells are open. FIG. 1 illustrates a conventional MBE architecture, showing three open effusion cells (shutters in open position) and one closed effusion cell (shutter in closed position).

It is known in the art that alternatively supplying different atoms to a MBE substrate can be advantageous to enable rapid surface mobility of one type of atom (e.g., Ga) when the other atom (e.g., As) is not being added to the surface. This technique is known as “migration-enhanced epitaxy” (“MEE”) and can improve the epitaxial growth of compound semiconductors using MBE. Prior-art MEE is achieved by opening and closing shutters (sequential shuttering) to limit exposure to one element at a time. Enhanced migration arises from a higher concentration gradient and therefore higher diffusion rate of a particular element. MEE can lead to better surface flatness compared to normal MBE growth. Films grown using a combination of MEE and MBE can be of higher structural quality than those grown by MBE alone.

U.S. Pat. No. 5,183,779 to Tadayon et al. (hereinafter, “Tadayon”) teaches that in MEE for growing GaAs, the Ga and As shutters are opened one at a time in a cyclic, non-overlapping manner. As a result, the Ga surface diffusion length becomes very large, even at low substrate temperatures. Low substrate temperatures are important for high-vapor-pressure materials to enable a sufficiently high sticking coefficient to bind on the layers being grown. According to Tadayon, if conventional MBE is used at low temperatures, e.g., 100-400° C., the Ga and As will stick to the substrate surface and form an amorphous layer. Tadayon speculates that the tendency of Ga to lump together in conventional MBE results in part from the lower mobility of Ga in the presence of As. By contrast, MEE permits a cycle time in which only Ga is present on the substrate surface, thereby enhancing Ga atom mobility. The higher mobility is particularly advantageous at low temperature, which otherwise generally causes lower mobility. The low-temperature MEE cycle thus permits the Ga atoms to be sufficiently mobile and reach appropriate crystal sites on which to bind, before the next As atom cycle.

MEE can enable epilayer growth with good optical quality at low substrate temperatures. However, as explained in U.S. Pat. No. 4,876,218 to Pessa et al. (hereinafter, “Pessa”), MEE is only used when necessary. The method described by Pessa includes a first step of growing a GaAs buffer layer by alternatively applying the elements of the GaAs compound to the surface of a substrate, one atomic layer at a time. In the formation of each atomic layer of the buffer layer, the growing surface is exposed to a vapor beam containing only Ga or only As. Then, the substrate is heated to a higher temperature and additional GaAs layers are grown in the buffer layer by applying both Ga and As simultaneously, i.e., conventional MBE is used for the rest of production. The GaAs buffer layer is relatively thin compared to the total thickness of the final GaAs device layer.

Pessa explains why MEE should only be used when necessary. First, MEE is slower than MBE, due to material being shuttered half the time. Second, the MBE shutters are designed to be opened at the start of the MBE process and then closed at the end of the process. The shutters in MBE are not designed to be repeatedly and sequentially opened and closed on short time scales, such as about once per second in MEE. This sequential shuttering in MEE is extremely problematic on the physical apparatus, leading to shutter fatigue and ultimately mechanical failure. Therefore, in conventional approaches, the MEE stage needs to be very short; most of the layer growth must occur in MBE without MEE.

The same conclusions are drawn about MEE limitations in U.S. Pat. No. 5,571,748 to Miyazawa et al. (hereinafter, “Miyazawa”) in which it is cautioned that MEE “is not suitable for mass production since the rate of crystal growth is exceedingly slow.” Miyazawa states that this drawback of MEE can be solved by only utilizing MEE for a portion of the overall process.

U.S. Pat. No. 5,637,530 to Gaines et al. (hereinafter, “Gaines”) also emphasizes that MBE is considerably simpler and less time-consuming than MEE. Gaines instructs that after using MEE for part of the procedure, MBE should then be used as soon as a layer of sufficient thickness to limit defect formation has been created by MEE.

U.S. Pat. No. 6,001,173 to Bestwick et al. (hereinafter, “Bestwick”) discusses the serious difficulty associated with MEE relating to the sequential nature of the process which makes the overall growth rate slow and the frequent operation of the shutters and valves leads to instrument failures.

Improvements are commercially desired in view of the aforementioned problems associated with the MEE technique, including mechanical shutter fatigue and low growth rates compared to conventional MBE crystal growth.

### SUMMARY OF THE INVENTION

The present invention addresses the aforementioned needs in the art, as will now be summarized and then further described in detail below.

Some variations of the invention provide a pulsed-beam-deposition apparatus, the pulsed-beam-deposition apparatus comprising a plurality of elemental effusion cells positioned to deposit elemental materials onto a revolving substrate held by a substrate holder, wherein the revolving substrate and the plurality of elemental effusion cells are configured, without the use of sequential shuttering, to limit direct exposure at any point on the revolving substrate to a maximum of one elemental effusion cell at a time.

By limiting direct exposure at any point on the revolving substrate to a single effusion cell, the point is directly exposed to only a single elemental beam pulse, rather than being exposed to multiple elemental beam pulses at the same time.

In some embodiments, in order to provide deposition uniformity, each of the elemental effusion cells incorporates a beam-forming nozzle that emits a radially graded beam that compensates for differential tangential velocity of the revolving substrate.

The pulsed-beam-deposition apparatus is preferably disposed within a vacuum chamber. It is possible for the vacuum chamber to be added at a later time, prior to operation of the pulsed-beam-deposition apparatus.

In some embodiments, the substrate is configured as a plurality of spatially separated substrates held by the rotatable substrate holder.

In some embodiments, the plurality of elemental effusion cells includes (i) one or more first elemental effusion cells containing a first element and (ii) one or more second elemental effusion cells containing a second element that is different than the first element. Optionally, there may be (iii) one or more third elemental effusion cells containing a third element. The elemental effusion cells may be solid-source effusion cells or gas-source effusion cells. There may be 6 to 12 elemental effusion cells, for example. Preferably, each of the elemental effusion cells is configured with a beam-forming nozzle.

For each of the elemental effusion cells, there is preferably disposed a shutter that (i) when closed, blocks the elemental materials from depositing onto the substrate; and (ii) when open, allows the elemental materials to deposit onto the revolving substrate.

In certain embodiments, the pulsed-beam-deposition apparatus comprises effusion cell thermal isolation shields disposed between each of the elemental effusion cells. The elemental effusion cells may optionally be isolated with a liquid nitrogen cryopanel.

Some variations provide a method of pulsed beam deposition, the method comprising:
(a) providing a revolving substrate held by a substrate holder;
(b) providing a plurality of elemental effusion cells each containing elemental materials, wherein the elemental effusion cells, when heated, collectively form elemental beams directed toward the revolving substrate; and
(c) depositing the elemental materials from the elemental beams onto the revolving substrate, wherein any point on the revolving substrate is directly exposed to a maximum of one elemental beam pulse at a time.

The method preferably does not employ co-deposition of distinct elemental materials at the same point and time on the revolving substrate. Instead, the method may employ sequential deposition of multiple elemental materials from distinct effusion cells that are in the unshuttered position at the same time. Any given point on a revolving substrate is directly exposed to only one of the elemental materials at one time, and then is directly exposed to another elemental material at another time, as the substrate revolves. For this reason, the method does not require sequential shuttering of the elemental effusion cells in order to ensure that any point on the revolving substrate is directly exposed to a maximum of one elemental beam pulse at a time.

In some method embodiments, the plurality of elemental effusion cells includes (i) one or more first elemental effusion cells containing a first element and (ii) one or more second elemental effusion cells containing a second element that is different than the first element. The elemental effusion cells may be solid-source effusion cells or gas-source effusion cells.

The revolving substrate is preferably configured as a plurality of spatially separated substrates held by the substrate holder. The beam is preferably perpendicular to the revolving substrate (and parallel to the axis of rotation of the substrate holder) for each of the elemental effusion cells.

In some methods, the elemental-beam pressure range is from about 10⁻⁴ Torr to about 10⁻¹² Torr.

Step (c) may be characterized by a growth rate from about 0.1 μm/hour to about 10 μm/hour.

Step (c) may be performed at a revolving speed from about 5 revolutions per minute to about 300 revolutions per minute. In certain embodiments, the direction of revolution of the revolving substrate is switched between clockwise and counterclockwise during step (c), by switching the direction of rotation of the substrate holder, such as to cause a doping change between n-type and p-type doping.

The method may further comprise recovering one or more products each comprising deposited elemental materials on the substrate.

The invention also provides a product produced by a process comprising a method disclosed. In some embodiments, a product produced by a process comprises the steps of:
(a) providing a revolving substrate held by a substrate holder;
(b) providing a plurality of elemental effusion cells each containing elemental materials, wherein the elemental effusion cells, when heated, collectively form elemental beams directed toward the revolving substrate;
(c) depositing the elemental materials from the elemental beams onto the revolving substrate, wherein any point on the revolving substrate is directly exposed to a maximum of one elemental beam pulse at a time; and
(d) recovering a product comprising the elemental materials deposited during step (c).

In some embodiments, the product is an epitaxial wafer, such as an epitaxial wafer with a diameter from about 1 inch to about 12 inches. The final product may contain one or more elements selected from the group consisting of B, Al, Ga, In, N, P, O, As, Sb, Bi, C, Si, Ge, Sn, Pb, Li, Na, K, Rb, Cs, Be, Mg, Ca, Sr, Ba, S, F, Cl, Br, I, Se, Te, Au, Pt, Cr, and Cd, for example.

### BRIEF DESCRIPTION OF THE DRAWINGS

FIG. 1 illustrates a conventional molecular beam epitaxy (MBE) architecture of the prior art.

FIG. 2 is a side view of an exemplary pulsed-beam-deposition apparatus comprising a plurality of elemental effusion cells positioned to deposit elemental materials onto a revolving substrate held by a rotatable substrate holder, wherein the rotatable substrate holder and the plurality of elemental effusion cells are configured to limit direct exposure at any point on the substrate to a maximum of one elemental effusion cell at a time.

FIG. 3 is a top view of an exemplary pulsed-beam-deposition apparatus in some variations of the invention, showing an arcuate substrate path relative to the effusion cells.

FIG. 4 is a top-view illustration showing a plurality of circular substrates disposed off-center on an annular substrate holder that rotates during operation, in some variations of the invention.

FIG. 5 illustrates an exemplary design of a beam-forming nozzle, to provide a uniform elemental flux across the full length of the beam-forming nozzle.

FIG. 6 illustrates an exemplary design of a beam-forming nozzle, to provide a uniform elemental flux across the full length of the beam-forming nozzle.

### DETAILED DESCRIPTION OF EMBODIMENTS OF THE INVENTION

The apparatus, systems, methods, and products of the present invention will be described in detail by reference to various non-limiting embodiments.

This description will enable one skilled in the art to make and use the invention, and it describes several embodiments, adaptations, variations, alternatives, and uses of the invention. These and other embodiments, features, and advantages of the present invention will become more apparent to those skilled in the art when taken with reference to the following detailed description of the invention in conjunction with the accompanying drawings.

As used in this specification and the appended claims, the singular forms “a,” “an,” and “the” include plural referents unless the context clearly indicates otherwise. Unless defined otherwise, all technical and scientific terms used herein have the same meaning as is commonly understood by one of ordinary skill in the art to which this invention belongs.

Unless otherwise indicated, all numbers expressing conditions, concentrations, dimensions, and so forth used in the specification and claims are to be understood as being modified in all instances by the term “about.” Accordingly, unless indicated to the contrary, the numerical parameters set forth in the following specification and attached claims are approximations that may vary depending at least upon a specific analytical technique.

The term “comprising,” which is synonymous with “including,” “containing,” or “characterized by” is inclusive or open-ended and does not exclude additional, unrecited elements or method steps. “Comprising” is a term of art used in claim language which means that the named claim elements are essential, but other claim elements may be added and still form a construct within the scope of the claim.

As used herein, the phrase “consisting of” excludes any element, step, or ingredient not specified in the claim. When the phrase “consists of” (or variations thereof) appears in a clause of the body of a claim, rather than immediately following the preamble, it limits only the element set forth in that clause; other elements are not excluded from the claim as a whole. As used herein, the phrase “consisting essentially of” limits the scope of a claim to the specified elements or method steps, plus those that do not materially affect the basis and novel characteristic(s) of the claimed subject matter.

With respect to the terms “comprising,” “consisting of,” and “consisting essentially of,” where one of these three terms is used herein, the presently disclosed and claimed subject matter may include the use of either of the other two terms, except when used in Markush groups. Thus in some embodiments not otherwise explicitly recited, any instance of “comprising” may be replaced by “consisting of” or, alternatively, by “consisting essentially of.”

The present invention is predicated on the design of a new system architecture that may be referred to as “pulsed beam deposition” (“PBD”). In pulsed beam deposition, effusion cells are aimed parallel to the axis of rotation and off-center of an annular-shaped substrate holder. This configuration results in pulsed, single-element substrate exposure and no co-deposition even when multiple sources (effusion cells) are open. Migration-enhanced epitaxy (MEE) is achieved automatically in PBD, with no need for sequential shuttering as is conventionally required. MEE is built into the PBD apparatus, reducing or eliminating shutter fatigue and enabling faster species migration and epitaxial growth rates.

What is provided in some variations is an apparatus having a plurality of elemental effusion cells positioned to deposit multi-elemental (compound) materials onto a revolving substrate held by a substrate holder, wherein the action of the revolving substrate limits direct exposure at any point on the substrate to a maximum of one of the elemental effusion cells at a time.

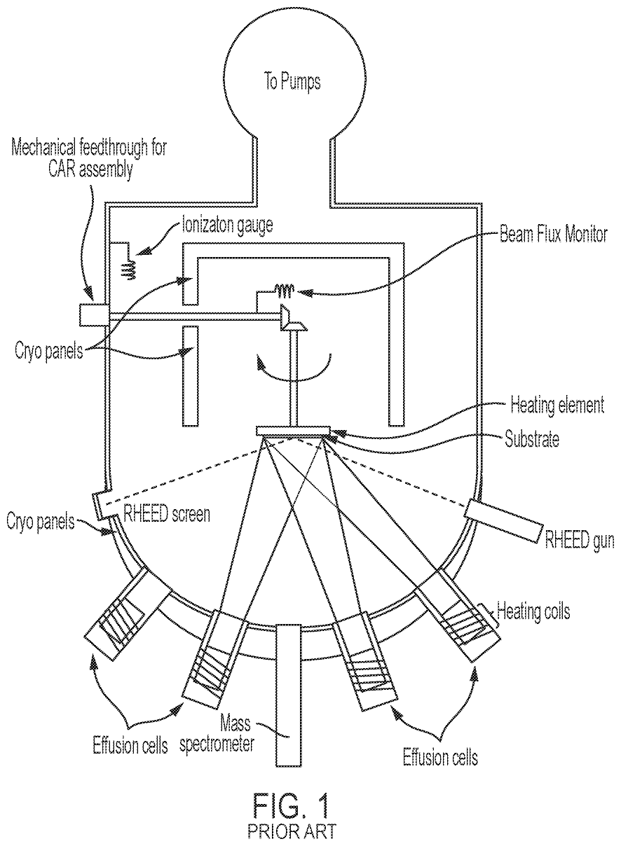

The prior-art MBE architecture aims effusion cells at an angle (not perpendicular to substrate) and on center of a disk-shaped substrate holder, resulting in multi-elemental substrate exposure and co-deposition when multiple effusion cells are open, as shown in FIG. 1. To achieve deposition uniformity, the distance of effusion cell to substrate is multiple times the substrate holder diameter.

By contrast, it has been discovered that by revolving a substrate and aiming effusion cells parallel to the axis of rotation and off-center of an annular-shaped substrate holder, the result is pulsed, single elemental substrate exposure without co-deposition when multiple effusion-cell sources are open. To achieve deposition uniformity, a beam-forming nozzle is preferably utilized, and there is a short distance of source to substrate holder.

Some variations of the invention provide a pulsed-beam-deposition apparatus, the pulsed-beam-deposition apparatus comprising a plurality of elemental effusion cells positioned to deposit elemental materials onto a revolving substrate held by a substrate holder, wherein the revolving substrate and the plurality of elemental effusion cells are configured, without the use of sequential shuttering, to limit direct exposure at any point on the revolving substrate to a maximum of one elemental effusion cell at a time.

By limiting direct exposure at any point on the revolving substrate to a single effusion cell, that point is directly exposed to only a single elemental beam pulse, rather than being exposed to multiple elemental beams at the same time. This is accomplished without the use of sequential shuttering, as is done in conventional MEE. Shutters may still be employed in the disclosed technology, but sequential shuttering is not required for MEE.

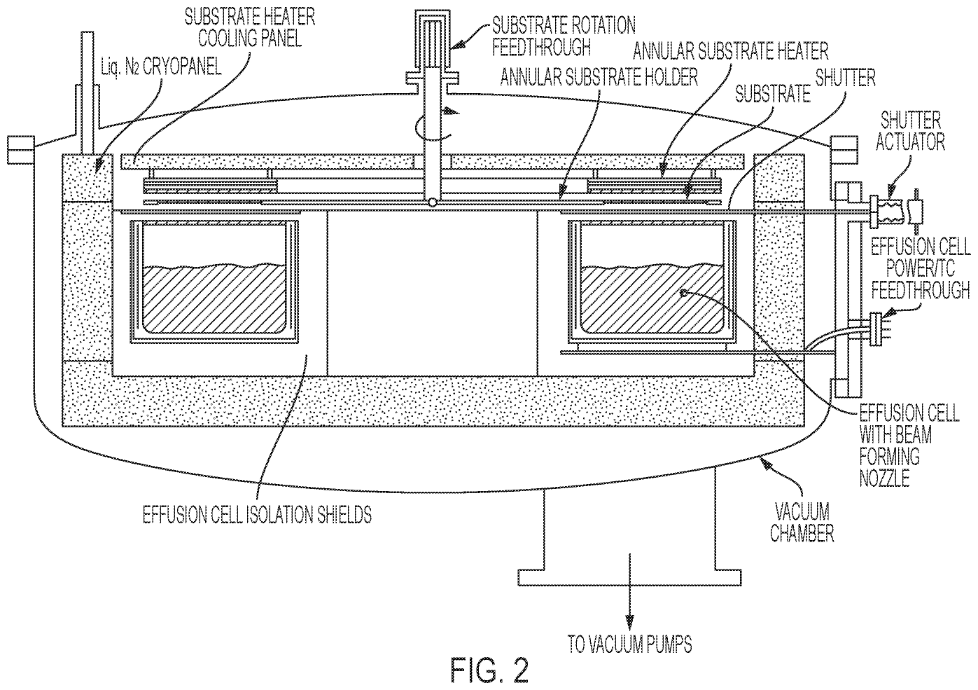

Some embodiments can be understood with reference to FIG. 2, which is a side view of an exemplary pulsed-beam-deposition apparatus (not drawn to scale). The pulsed-beam-deposition apparatus is not in a frustoconical architecture, as is the case with a conventional MBE apparatus (see FIG. 1). In FIG. 2, there is a plurality of revolving substrates disposed on an annular substrate holder. The annular substrate holder is disposed in thermal communication with an annular substrate heater. The substrate heater is distally positioned above the annular substrate holder relative to the side that is exposed to the upward-facing effusion cells. A substrate heater cooling panel is disposed in thermal communication with the substrate heater. The annular substrate holder is rotatable using the substrate rotation feedthrough, or other rotation means. There is a plurality of effusion cells each configured with a beam-forming nozzle. An effusion cell is in electrical communication with a power source configured to heat up the material within the effusion cell so that the material vaporizes, effuses through the beam-forming nozzle in the direction of the substrate, and deposits onto the substrate surface (or the surface of a layer after a period of growth). Because FIG. 2 is a side view, only two effusion cells, two shutters, and two substrates are shown, it being understood that more than two effusion cells, two shutters, and two substrates are generally present in the apparatus. There is an effusion cell power feedthrough which may also be a thermocouple (TC) feedthrough, or there may be separate feedthrough for the power supply and a thermocouple. Each effusion cell is equipped with a shutter, in the flow path of the beam from the beam-forming nozzle to the substrate. Each shutter may be open or closed, as dictated by the respective shutter actuator. Optionally, effusion cell thermal isolation shields are disposed between each effusion cell to thermally isolate the effusion cells from each other. A liquid N₂ cryopanel is disposed at the periphery of the apparatus, between the internal components and the chamber wall. The entire apparatus of FIG. 2 is contained within a vacuum chamber equipped with one or more vacuum pumps to maintain ultra-high vacuum during operation. In some embodiments, the pulsed-beam-deposition apparatus is fabricated and potentially shipped without the vacuum chamber.

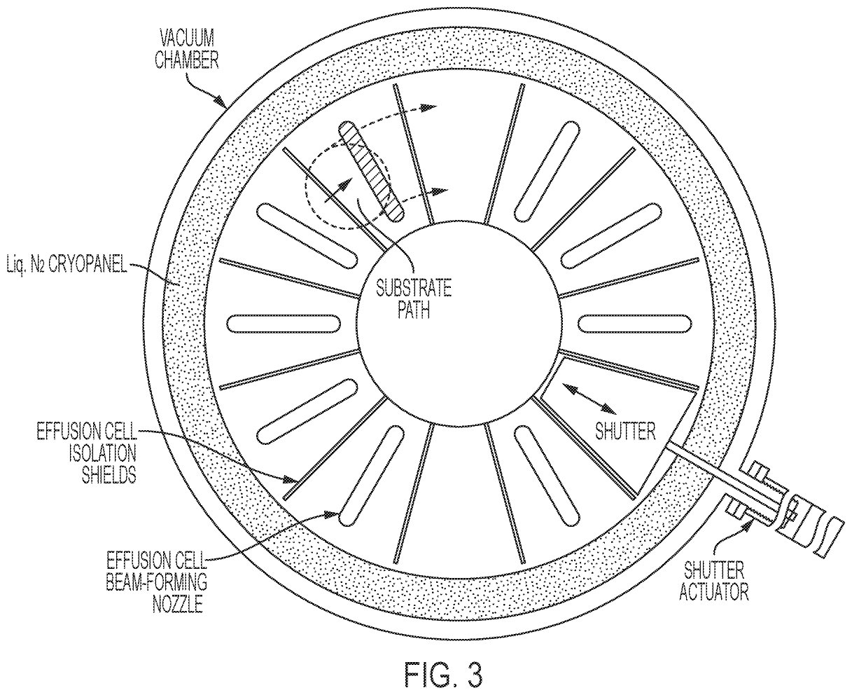

Some embodiments can be understood with reference to FIG. 3, which is a top view of an exemplary pulsed-beam-deposition apparatus (not drawn to scale). In FIG. 3, there is a plurality of circular revolving substrates disposed on an annular substrate holder. The annular substrate holder is rotatable, and its rotation results in an arcuate substrate path illustrated in FIG. 3 (see the dotted arrows in the clockwise direction). The rotation of the substrate holder results in revolution of each of the substrates in FIG. 3; in the frame of reference of a single substrate, that substrate is revolving around the center axis of the substrate holder, in a plane. In FIG. 3, there are 10 effusion cells each configured with a beam-forming nozzle. Each effusion cell is configured to heat up the material within the effusion cell so that the material vaporizes, effuses through the beam-forming nozzle perpendicular to the revolving substrate, and deposits onto the revolving substrate surface (or the surface of a layer after a period of growth). The effusion cells are not shown in the view of FIG. 3. Each effusion cell is equipped with a shutter, in the flow path of the elemental beam from the beam-forming nozzle to the revolving substrate. Each shutter may be open or closed, as indicated by the double arrow in FIG. 3. Optionally, effusion cell isolation shields are disposed between each effusion cell to thermally isolate the effusion cells from each other. A liquid N₂ cryopanel is disposed at the periphery of the apparatus, between the internal components and the chamber wall. The entire apparatus of FIG. 3 is contained within a vacuum chamber.

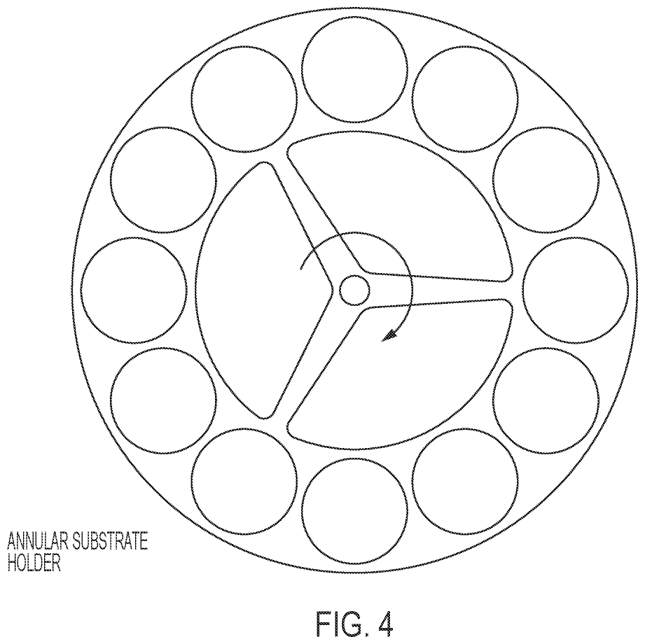

FIG. 4 is a top-view illustration similar to FIG. 3. In FIG. 4, there are 12 circular revolving substrates disposed on an annular substrate holder. When the annular substrate holder is rotating during operation, the direction of rotation (as well as the direction of revolution of each substrate) is shown in FIG. 4 as being clockwise, noting that counterclockwise rotation may also be used, such as for a doping change. The 12 revolving substrates are off-center of the annular substrate holder—that is, there is no substrate at or very near the center of the annular substrate holder. FIG. 4 also depicts three substrate holder support spokes between the center axis and the outer annulus containing the 12 revolving substrates.

In embodiments such as those shown in FIG. 4, there is a plurality of spatially separated substrates held by a rotatable, annular substrate holder. The spatially separated substrates are typically circular and may be referred to as disks. While FIG. 4 shows 12 individual revolving substrates, other numbers of revolving substrates are possible. The number of spatially separated substrates may be 4, 5, 6, 7, 8, 9, 10, 11, 12, 13, 14, 15, 16, 17, 18, 19, 20, or more, for example. In alternative embodiments, the spatially separated substrates may be non-circular, such as oval-shaped, square, rectangular, or polygonal, for example. In a certain alternative embodiment, there is a single revolving substrate that forms a continuous annulus off-center of the annular substrate holder.

The plurality of elemental effusion cells may be from 6 to 12 elemental effusion cells, for example. In the illustration of FIG. 3, for instance, there are 10 elemental effusion cells. In various embodiments, the number of effusion cells is 6, 7, 8, 9, 10, 11, 12, or more. The plurality of elemental effusion cells typically includes (i) one or more first elemental effusion cells (e.g., from 3 to 6 first elemental effusion cells) containing a first element (e.g., Ga) and (ii) one or more second elemental effusion cells (e.g., from 3 to 6 second elemental effusion cells) containing a second element (e.g., As) that is different than the first element. In certain embodiments, the plurality of elemental effusion cells further includes (iii) one or more third elemental effusion cells (e.g., from 1 to 3 third elemental effusion cells) containing a third element (e.g., Al). The third elemental effusion cells may provide dopants to the growing layer, for example.

In general, an elemental effusion cell is a source of a thermally evaporated atomic or molecular beam. An elemental effusion cell contains a crucible formed of a refractory material (typically pyrolytic boron nitride), and heated to a temperature at which a beam of atoms or molecules is thermally excited and emitted toward a revolving substrate. Elemental effusion cells may also be designed for gas sources or plasma sources to deliver atoms to the substrate, in GSMBE or plasma-assisted MBE, for example. The temperature of each effusion cell is preferably monitored using a thermocouple since temperature is usually the primary factor in the effusion rate for a given cell geometry. The effusion-cell crucibles may be fabricated from a material selected from the group consisting of pyrolytic boron nitride, silicon carbide, quartz, tungsten, tantalum, iridium, beryllium oxide, aluminum oxide, graphite, and combinations thereof, for example.

For each of the elemental effusion cells, there is preferably disposed a shutter that (i) when closed, blocks the elemental materials from depositing onto the revolving substrate; and (ii) when open, allows the elemental materials to deposit onto the revolving substrate. Shutters are well-known components of MBE systems. When an elemental effusion cell is heated (typically via electrical power) and unshuttered, the desired epitaxial growth is accomplished on the revolving substrate. When an elemental effusion cell is shuttered, i.e. the shutter is closed (see FIG. 3), the elements contained in that effusion cell, even if heated, cannot escape the effusion cell to reach the revolving substrate. The shutters are controlled using shutter actuators that are preferably actuated using a computer-automated shutter control system.

The pulsed-beam-deposition apparatus optionally comprises effusion cell thermal isolation shields disposed between each of the elemental effusion cells. The thermal isolation shields thermally isolate the effusion cells from each other, so that each effusion cell may be maintained at its desired temperature. In some embodiments employing the thermal isolation shields, the shields capture and direct heat during operation, and may form a highly emissive blackbody thermal cavity to assist in uniformly heating the crucible and the source material. Materials for the thermal isolation shields may be the same as, or different than, the crucible materials of the effusion cells. The optional thermal isolation shields may be fabricated from a material selected from the group consisting of pyrolytic boron nitride, silicon carbide, quartz, tungsten, tantalum, molybdenum, iridium, beryllium oxide, aluminum oxide, graphite, pyrolytic graphite, and combinations thereof, for example. When the effusion cell thermal isolation shields are not present, then the 12 shields illustrated in FIG. 3 may instead be regarded as dividing lines between adjacent effusion cells.

In order to enhance deposition uniformity, each of the elemental effusion cells is preferably configured with a beam-forming nozzle. The beam-forming nozzle is designed for a desired beam shape. The beam-forming nozzle may be configured with one or a plurality of apertures through which atoms may effuse. In some embodiments, a beam-forming nozzle is configured with a plurality of apertures that have varying aperture size, increasing in size in the direction away from the center axis of the substrate holder. Larger aperture sizes at increasing distance from the center axis allow for a uniform beam flux across the entire nozzle. This design feature recognizes that mathematically, the local revolution velocity scales with the radial length from the center. This can be understood in FIG. 3, where at the 11 o'clock position, two arrows are shown for the effusion cell beam-forming nozzle, with a longer arrow depicted at the location closest to the outer region of the substrate holder, qualitatively corresponding to a higher local revolution velocity there. The nozzle may be designed so that the effusion rate is a function of substrate-holder radial position, in order to maintain a uniform deposition rate across the revolving substrate.

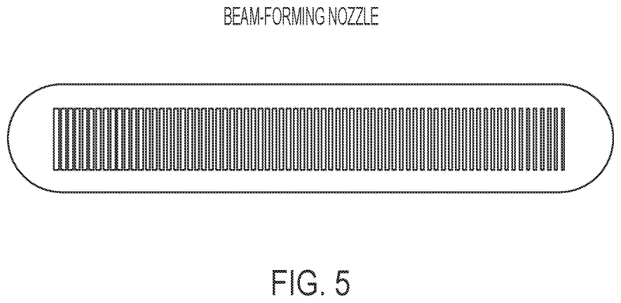

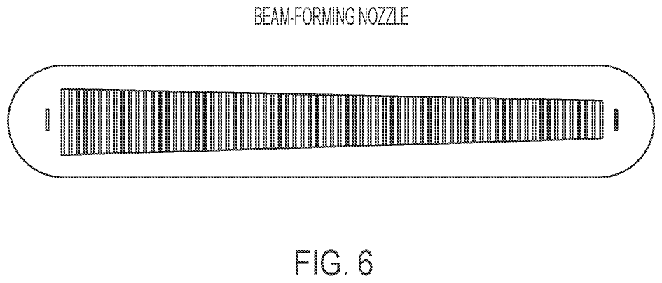

In some embodiments, a beam-forming nozzle emits a radially graded beam that compensates for differential tangential velocity of the revolving substrate. Two examples are depicted in FIGS. 5 and 6.

FIG. 5 illustrates an exemplary design of a beam-forming nozzle, in which the left side of the drawing corresponds to the location closest to the outer region of the substrate holder, and the right side of the drawing corresponds to the location closest to the rotation axis of the substrate holder. In FIG. 5, the nozzle gap spacing (gap width) is highest at the location closest to the outer region, to provide the same elemental flux to the revolving substrate as at the location closest to the rotation axis. One skilled in the art can calculate the nozzle gap spacings in order to achieve a uniform elemental flux across the full length of the beam-forming nozzle.

FIG. 6 illustrates an exemplary design of a beam-forming nozzle, in which the left side of the drawing corresponds to the location closest to the outer region of the substrate holder, and the right side of the drawing corresponds to the location closest to the rotation axis of the substrate holder. In FIG. 6, the nozzle gap spacing is constant but the nozzle gap lengths are tapered, being longest at the location closest to the outer region, to provide the same elemental flux to the revolving substrate as at the location closest to the rotation axis. One skilled in the art can calculate the nozzle gap lengths in order to achieve a uniform elemental flux across the full length of the beam-forming nozzle.

The distance from the beam-forming nozzle to the revolving substrate surface is preferably as close as possible, to minimize waste. Such distance, for example, may be from about 1 centimeter to about 10 centimeters.

In some embodiments, the beam-forming nozzles for all effusion cells are the same design. In other embodiments, different designs are utilized for different beam-forming nozzles in the apparatus.

The beam-forming nozzle may be fabricated from a material selected from the group consisting of pyrolytic boron nitride, silicon carbide, quartz, tungsten, tantalum, iridium, beryllium oxide, aluminum oxide, graphite, and combinations thereof, for example. The beam-forming nozzle is preferably fabricated from pyrolytic boron nitride (PBN).

As stated above, a beam-forming nozzle may be configured with multiple apertures through which atoms may effuse. There may be multiple beam-forming nozzles configured for a single elemental effusion cell. There is not necessarily a one-to-one correspondence between the number of elemental effusion cells and the number of beam-forming nozzles. FIG. 3 depicts one beam-forming nozzle for each effusion cell. Certain variations of this configuration place multiple (e.g., two or three) beam-forming nozzles in each effusion cell, or in some of the effusion cells. In such variations, there may be exposure of a given substrate disk to two elemental effusion cells as the substrate is revolving, due to the use of multiple beam-forming nozzles for an effusion cell. With reference again to FIG. 3, the revolving substrate is shown during revolution from the 10 o'clock position to the 11 o'clock position (“substrate path” in FIG. 3), where each position corresponds to distinct elemental effusion cells. Because of the gap (length) between adjacent beam-forming nozzles relative to the disk diameter, in the embodiment of FIG. 3, the revolving substrate disk cannot be exposed to more than one effusion cell at any point in time. When for example each of the effusion cells (in the 10 o'clock and 11 o'clock positions) contains three beam-forming nozzles, the substrate disk for a small period of time will be exposed to both effusion cells as the disk revolves from the 10 o'clock position to the 11 o'clock position. Nevertheless, on average, the period of time for which the substrate disk is exposed to both effusion cells is small relative to the time for which the substrate disk is exposed to a single effusion cell. At a minimum, during revolution, the revolving substrate disk is exposed to a single effusion cell a majority (at least 51%) of the time.

In this specification, the elemental effusion cells are configured to limit direct exposure at any point on the revolving substrate to a maximum of one elemental effusion cell at a time, which means at least 51% of the time, preferably means at least 75% of the time, more preferably means at least 90% of the time, and most preferably means at least 91%, 92%, 93%, 94%, 95%, 96%, 97%, 98%, 99%, or 100% of the time. Depending on the sizes of beam-forming nozzles and revolving substrates, it is possible that at a snapshot in time, a revolving substrate is exposed to more than one elemental effusion cells. In preferred embodiments, however, the revolving substrate and the elemental effusion cells are configured to limit direct exposure at any point on the revolving substrate to a maximum of one elemental effusion cell at a time.

The elemental effusion cells may be isolated with a liquid nitrogen (N₂) cryopanel. When it is desired to cool the revolving substrate, the ultra-high vacuum environment within the growth chamber may be maintained by a system of cryopanels and cryopumps, turbopumps, ion pumps, and sublimation pumps, chilled using liquid N₂ to a temperature of about −196° C. (boiling point of N₂). In some embodiments, the whole deposition region is surrounded by cryopanels, with minimal apertures provided for access of components and for substrate transfer. The material for the cryopanel is preferably selected to ensure adequate strength to withstand frequent thermal cycling from −196° C. to ambient temperatures. In principle, liquid nitrogen may be replaced by cold, gaseous nitrogen depending on overall temperature and vacuum requirements. Also, other cryogenic liquids may be employed, such as (but not limited to) helium and argon.

Some variations provide a method of pulsed beam deposition, the method comprising:
(a) providing a revolving substrate held by a substrate holder;
(b) providing a plurality of elemental effusion cells each containing elemental materials, wherein the elemental effusion cells, when heated, collectively form elemental beams directed toward the revolving substrate; and
(c) depositing the elemental materials from the elemental beams onto the revolving substrate, wherein any point on the revolving substrate is directly exposed to a maximum of one elemental beam pulse at a time.

Pulsed beam deposition (PBD) employs pulses of elemental beams that impinge a revolving substrate. In this specification, a “pulse” means a single sudden change in a property of a medium or a quantity. A pulse has a sharp rise and a sharp decline in amplitude. The pulsing is best understand in the frame of reference of a single point on the revolving substrate. In that frame of reference, the substrate point revolves until it is exposed to the elemental effusion cell, at which time the substrate point undergoes strong exposure to the elemental beam. After that exposure, as the substrate point continues to revolve, the substrate point is again no longer exposed to that particular elemental beam (from the elemental effusion cell). The net effect is one of pulsing. The amplitude and sharpness of the pulse will generally depend on the revolution speed and the effusion rate (which itself depends on temperature).

In prior-art MBE/MEE architecture, substrates are exposed to relatively low-amplitude continuous elemental beams. By contrast, using the disclosed PBD architecture, revolving substrates are exposed to higher-amplitude pulses compared to the amplitude of continuous beams used in MBE/MEE. For example, the PBD elemental beam pulse amplitude may be 10× to 100× of the amplitude of MBE/MEE continuous beams. Also, the PBD elemental beam pulse impinges the revolving substrate perpendicular to the substrate surface, not at an angle, as in prior-art MBE/MEE architectures.

In some embodiments, the plurality of elemental effusion cells includes (i) one or more first elemental effusion cells containing a first element and (ii) one or more second elemental effusion cells containing a second element that is different than the first element. Optionally, there may be (iii) one or more third elemental effusion cells containing a third element.

In some embodiments employing solid-source MBE, elements in the elemental effusion cells may be in monoatomic or polyatomic form, either in the solid (evaporant) phase within the effusion cell or in the vapor phase formed from the effusion cell. For example, arsenic may be formed from an effusion cell as atomic arsenic (As), diatomic arsenic (As₂), arsenic tetramer (As₄), or a combination thereof. Such polyatomic elements may then be deposited on the substrate surface and may exist for a period of time until individual atoms bond with other types of atoms (e.g., As bonding with Ga). The term “elemental” in describing an effusion cell is in reference to the fact that elements (not precursor molecules) are ultimately deposited and grown during fabrication.

In some embodiments employing gas-source MBE, an elemental effusion cell contains a gas which itself comprises an element of interest. Examples include nitrogen (N) in ammonia (NH₃), phosphorus (P) in phosphine (PH₃), and indium (In) in trimethylindium (In(CH₃)₃). Ammonia, phosphine, and trimethylindium (a metal-organic gas) are precursor gases for N, P, and In, respectively. In step (c), the precursor gas may decompose to the element of interest, typically via thermal cracking, in the effusion cell.

In some methods, the revolving substrate is configured as a plurality of spatially separated substrates held by the rotatable substrate holder. It is preferred that none of the revolving substrates are on center of the axis of rotation of the rotatable substrate holder, since there is no revolution or pulsing effect at the exact center.

The method preferably does not employ co-deposition of distinct elemental materials at the same point and time on the revolving substrate. Co-deposition refers to multiple different species being deposited at the same point on the revolving substrate at the same time, as in conventional MBE. The absence of co-deposition is a technical advantage for the present invention, because it allows automatic migration-enhanced epitaxy throughout the entire fabrication process. Co-deposited atoms fundamentally prevent migration-enhanced epitaxy. It will be understood that while co-deposition is not intended, a small amount of co-deposited elements may arise due to desorbed atoms from a previous layer, stray atoms, or impurities (e.g., <1 wt % concentration).

The method preferably does not utilize sequential shuttering of the elemental effusion cells. In this specification, “sequential shuttering” refers to a shutter being opened and closed on a time scale of 10 seconds or less, such as 1 second or less. The time scale of shuttering in variations of this invention is at least 1 minute, such as at least 10 minutes, or at least 1 hour, for example. The shuttering frequency in this invention is dictated by the number of distinct layers (with different compositions) being fabricated. Even when there are many distinct layers in a wafer being fabricated, the time scale of shuttering for each layer is still at least 1 minute, significantly longer than the time scale in sequential shuttering.

This invention beneficially provides built-in, automatic migration-enhanced epitaxy without the need for sequential shuttering. For each elemental effusion cell, there is disposed a shutter that (i) when closed, blocks the respective elemental material from depositing onto the revolving substrate; and (ii) when open, allows the respective elemental material to deposit onto the revolving substrate. During growth, at least one shutter is open. During growth of a certain layer, shutters will be open or closed based on the desired elements to be deposited. Notably, the open/closed position for a given shutter remains the same during the entire growth of that layer, in the present invention. No sequential shuttering during layer growth is necessary, since the revolution of the substrate instead automatically and continuously provides migration-enhanced epitaxy. Rather than sequential shuttering, the rotating substrate holder exposes the revolving substrate to the elemental beam, ensuring that direct beam exposure is limited at any point on the revolving substrate to a maximum of one effusion cell (and thus one elemental beam pulse) at a time.

Preferably, the elemental beam is perpendicular to the revolving substrate surface for each of the elemental effusion cells. In certain embodiments, the beam is configured at an angle for some or all of the elemental effusion cells, but this is less preferred than perpendicular beams. The average angle between the elemental beam and the revolving substrate surface is preferably 90°±10°, more preferably 90°±5°, even more preferably 90°±2°, and most preferably 90°±1°, such as 90°±0.5°, 90°±0.1°, or exactly (precisely perpendicular).

The method may be conducted in a substrate temperature range from about 200° C. to about 1000° C., such as about 200° C., 300° C., 400° C., 500° C., 600° C., 700° C., 800° C., 900° C., or 1000° C., for example. Higher temperatures are also possible. The selection of substrate temperature will generally depend on the material being fabricated, the desired growth rate, and the desired crystallographic quality. Because migration-enhanced epitaxy occurs throughout the disclosed method, it is possible in some embodiments to keep the substrate temperature lower than in traditional MBE/MEE. This has various benefits including higher sticking coefficients and more efficient epitaxial growth. The temperature may vary during fabrication of a wafer, such as when there are multiple layers having different compositions.

The method may be conducted in a pressure range from about 10⁻⁴ Torr to about 10⁻¹² Torr, such as about 10⁻⁵ Torr, 10⁻⁶ Torr, 10⁻⁷ Torr, 10⁻⁸ Torr, 10⁻⁹ Torr, 10⁻¹⁰ Torr, 10⁻¹¹ Torr, or 10⁻¹² Torr, for example. The pressure may vary during fabrication of a wafer, such as when there are multiple layers having different compositions.

Step (c) may be characterized by a growth rate from about 0.1 μm/hour to about 10 μm/hour, for example (μm=10⁻⁶ m=micron). An exemplary growth rate is about 1 μm/hour. In various embodiments, the growth rate in step (c) is about 0.1, 0.2, 0.4, 0.5, 0.6, 0.7, 0.8, 0.9, 1, 1.5, 2, 3, 4, 5, 6, 7, 8, 9, or 10 μm/hour, for example. The growth rate may vary during fabrication of a wafer, such as when there are multiple layers having different compositions.

Step (c) may be performed at a revolving speed from about 5 revolutions per minute to about 300 revolutions per minute, for example. An exemplary revolving speed is about 60 revolutions per minute (rpm) which enables a deposition of about 1 monolayer per pulse and a growth rate of about 1 micron/hour. In various embodiments, the revolving speed of the revolving substrate is about 5, 10, 15, 20, 25, 30, 35, 40, 50, 100, 150, 200, 250, or 300 rpm. Mathematically, the revolving speed of each individual, circular substrate region (see FIG. 4) is equal to the rotational speed of the substrate holder.

The revolution in step (c), from the frame of reference of a single spot on the revolving substrate, results in a pulsed beam of first atoms and a temporally distinct pulsed beam of second atoms. This can be seen in FIG. 3, where the revolving substrate, as the substrate holder is being rotated, suddenly is exposed to a beam from the effusion cell that is equipped with that particular nozzle (shaded in FIG. 3, at the 11 o'clock position). As the substrate holder continues to rotate, in the frame of reference of the single spot, the beam stops and another beam starts, either immediately or after a delay time. The overall result is pulsed beam deposition.

Pulsed beam deposition is sequential deposition, not co-deposition. Depending on the sequence of effusion cells, the sequence of elements being deposited may vary. For example when there are first effusion cells containing element A and second effusion cells containing element B (generic second element, not referring to boron), the sequence may be A, B, A, B, . . . ; A, none, B, none, . . . ; A, B, none, A, B, none, . . . ; A, A, B, B, none, A, A, B, B, none; or other oscillation strategies. A “none” pulse may be referred to as a delay time or dead time, and may result when a shutter is closed (e.g., FIG. 3 at 4 o'clock position), or when there is a region with no effusion cell (e.g., FIG. 3 at 6 o'clock position).

The method may further comprise recovering one or more products each comprising deposited elemental materials, after the revolving substrate is stopped. A product may be referred to as an epitaxial wafer, in some embodiments. The epitaxial wafer may have a diameter from about 1 inch to about 12 inches, for example. In the embodiment of FIG. 4, 12 individual epitaxial wafers are produced. After depositional growth onto a revolving substrate, a wafer is cooled, inspected, and further processed (e.g., stored, sold, incorporated into a device, etc.).

The products may contain one or more elements selected from the group consisting of B, Al, Ga, In, N, P, O, As, Sb, Bi, C, Si, Ge, Sn, Pb, Li, Na, K, Rb, Cs, Be, Mg, Ca, Sr, Ba, S, F, Cl, Br, I, Se, Te, Au, Pt, Cr, and Cd, for example. Many materials, dopants, layer configurations, and bandgaps are possible using the present invention.

In some embodiments, a product incorporates one or more Group III elements selected from B, Al, Ga, or In. In some embodiments, a product incorporates one or more Group V elements selected from N, P, As, or Sb.

One or more dopants (or doping agents) are introduced when doping is desired. Doping is the intentional introduction of impurities into an intrinsic semiconductor for the purpose of modulating its electrical, optical, and structural properties. The doped material is referred to as an extrinsic semiconductor. In an extrinsic semiconductor, dopant atoms in the crystal lattice provide charge carriers which carry electric current through the crystal. The doping agents used are of two types, resulting in two types of extrinsic semiconductors. An electron donor dopant is an atom which, when incorporated in the crystal, releases a mobile conduction electron into the crystal lattice. An extrinsic semiconductor which has been doped with electron donor atoms is called an n-type semiconductor, because the majority of charge carriers in the crystal are negative electrons. An electron acceptor dopant is an atom which accepts an electron from the lattice, creating a vacancy (a “hole”) where an electron should be. The hole can move through the crystal like a positively charged particle. An extrinsic semiconductor which has been doped with electron acceptor atoms is called a p-type semiconductor, because the majority of charge carriers in the crystal are positive holes. In general, increased doping leads to increased conductivity due to the higher concentration of carriers.

As mentioned earlier, a doping change may be accomplished by changing the direction of revolution of the revolving substrate. It is known from Tadayon (cited above) that one can control the donor/acceptor characteristics of a Si dopant in GaAs by timing the opening of a Si shutter to coincide with the opening of a Ga or As shutter. In the present invention, by changing the direction of the revolving substrate from clockwise to counterclockwise, the Si dopant may switch from an n-type dopant to a p-type dopant (or vice versa). This doping option is a unique feature of pulsed beam deposition as disclosed herein.

In some embodiments, a product incorporates one or more Group III elements and optionally one or more dopants selected from the group consisting of Bi, C, Si, Ge, Sn, Pb, Li, Na, K, Rb, Cs, Be, Mg, Ca, Sr, Ba, S, F, Cl, Br, I, Se, Te, Au, Pt, Cr, Cd, and O.

In some embodiments, a product incorporates one or more Group V elements and optionally one or more dopants selected from the group consisting of Bi, C, Si, Ge, Sn, Pb, Li, Na, K, Rb, Cs, Be, Mg, Ca, Sr, Ba, S, F, Cl, Br, I, Se, Te, Au, Pt, Cr, Cd, and O.

In some preferred embodiments, a product incorporates one or more Group III elements as well as one or more Group V elements, in III-V compound semiconductors, e.g., GaAs, GaSb, GaN, AlN, InP, InAs, AlGaAs, InGaAs, AlGaN, InAlAs, AlGaSb, etc.

Elements that are not Group III or Group V elements may be utilized, especially when fabricating non-semiconductor structures (e.g., conducting layers or insulating layers), or when incorporating dopants into the product. In some embodiments, a product incorporates one or more Group III elements as well as one or more Group V elements, as well as one or more dopants selected from the group consisting of Bi, C, Si, Ge, Sn, Pb, Li, Na, K, Rb, Cs, Be, Mg, Ca, Sr, Ba, S, F, Cl, Br, I, Se, Te, Au, Pt, Cr, Cd, and O. In some embodiments, a product incorporates one or more Group III elements as well as oxygen. An example is gallium oxide, Ga₂O₃, which is an ultrawide-bandgap semiconductor material.

The revolving substrate may contain one or more elements selected from the group consisting of B, Al, Ga, In, N, P, O, As, Sb, Bi, C, Si, Ge, Sn, Pb, Li, Na, K, Rb, Cs, Be, Mg, Ca, Sr, Ba, S, F, Cl, Br, I, Se, Te, Au, Pt, Cr, and Cd, for example. In some embodiments, the revolving substrate is essentially an initial layer of the intended crystals (e.g., GaAs) to be fabricated. In some embodiments, the revolving substrate material is different than the first deposition layer and potentially different than any of the deposition layers to be formed during fabrication. In some preferred embodiments, the revolving substrate is selected for good epitaxial fit (crystal lattice matching) with the first layer, to avoid crystallographic strain in the first layer and the negative impact on the rest of the deposition process. In other embodiments employing heteroepitaxy, one kind of crystal is grown on a revolving substrate surface having a different type of crystal. An example of heteroepitaxy is a gallium arsenide layer grown on a silicon substrate (GaAs/Si heteroepitaxy).

Bandgap-engineered structures may be fabricated via pulsed beam deposition of epitaxial layers. Many layers may be formed by repeating the methods disclosed herein via atom-by-atom addition. For each layer, the applicable effusion cells are opened or closed, depending on the desired chemical composition of the respective layer. During growth of a layer, migration-enhanced epitaxy occurs due to the pulsed beam deposition as described in this specification. The chemistry (kinetics and thermodynamics) controls the epitaxy so that, for example, Ga bonds only to N, forming GaN, rather than forming Ga—Ga bonds or N—N bonds (such antisite defects may arise but are typically in the parts per trillion concentration). An example structure includes multiple layers of GaN, followed by a layer of AlN, multiple layers of AlGaN, and then one or more layers of GaN, in the direction away from the surface of the revolving substrate. Because the composition of each layer may be independently selected, many types of graded structures, dopant profiles, and bandgap patterns are possible.

The present invention provides a product produced by a process comprising the steps of:
(a) providing a revolving substrate held by a substrate holder;
(b) providing a plurality of elemental effusion cells each containing elemental materials, wherein the elemental effusion cells, when heated, collectively form elemental beams directed toward the revolving substrate;
(c) depositing the elemental materials from the elemental beams onto the revolving substrate, wherein any point on the revolving substrate is directly exposed to a maximum of one elemental beam pulse at a time; and
(d) recovering a product comprising the elemental materials deposited during step (c).

In some embodiments, the product is an epitaxial wafer, such as an epitaxial wafer with a diameter from about 25 millimeters to about 300 millimeters, for example. The epitaxial wafer may have a thickness from about 1 micron to about 500 microns, for example. The final product may contain one or more elements selected from the group consisting of B, Al, Ga, In, N, P, O, As, Sb, Bi, C, Si, Ge, Sn, Pb, Li, Na, K, Rb, Cs, Be, Mg, Ca, Sr, Ba, S, F, Cl, Br, I, Se, Te, Au, Pt, Cr, and Cd, for example.

In some embodiments, the product is characterized by a unique, observable physical or chemical property that is evidence that the principles of the invention had been utilized. For example, there can be an absence of an analog variation in composition, surface roughness, and/or crystallographic epitaxial fit toward the outer diameter of a given wafer. By contrast, the product produced by a process disclosed herein may be characterized by a digital variation in composition, surface roughness, and/or crystallographic epitaxial fit toward the outer diameter of a given wafer, where the digital variation arises directly from the pulsed beam deposition. The digital variation forms a pattern that can be observed using suitable imaging techniques, such as (but not limited to) scanning electron microscopy (SEM); transmission electron microscopy (TEM); X-ray tomography (XRT), positron emission tomography (PET), and magnetic resonance imaging (MRI), for example. The digital pattern indicates a surface signal uniformity that proves there is a low degree of variation of the composition, surface roughness, and/or crystallographic epitaxial fit across the wafer. Not only can such imaging show high wafer quality and lateral uniformity, but the imaging can also be performed to prove that the method and system of the invention were employed to make the wafer.

The wafer quality may be high, according to the invention—not only in the lateral direction but also in the depth dimension. The initial nucleation in traditional MBE takes place through three-dimensional islands. Without being limited by theory, it is believed that pulsed beam deposition enables growth that is essentially planar, in layer-by-layer stacking, with two-dimensional nucleation that is parallel to the interface. Two-dimensional growth, in turn, may cause reduction in lattice strain and confinement of defects formed in the growth within a narrower interface region than in MBE.

The principles of the invention may be applied to other structures besides pure epitaxial wafers. In some embodiments, selective area epitaxy is employed. Selective area epitaxy is the local growth of an epitaxial layer through a patterned dielectric mask (e.g., SiO₂ or Si₃N₄) deposited on a semiconductor substrate. Epitaxial growth conditions are selected to ensure epitaxial growth occurs on the exposed substrate, but not on the dielectric mask. The selectivity of the growth arises from the property that effused atoms have a low sticking coefficient on the mask. The patterns (holes) in the mask may be fabricated using standard microfabrication techniques, such as lithography or etching. Selective area epitaxy enables semiconductor nanostructures such as quantum dots and nanowires to be grown.

The principles of the invention may be applied to three-dimensional integrated circuits. For example, a plurality of wafers (as provided herein) may be stacked and interconnected vertically using, for example, through-silicon vias or copper connections, so that the wafers collectively behave as a single device. In various embodiments, a plurality of wafers (as provided herein) may be utilized to produce stacked integrated circuits, monolithic integrated circuits, heterogeneously integrated circuits, wafer-level packaging, and other microelectronics and nanoelectronics.

The systems and methods described herein may be designed with the aid of physics-based models, such as finite element models. Physics-based models may be developed to simulate heat transport, mass transport (including species migration at the substrate surface), reaction kinetics, chemical equilibrium, thermal stresses, and other physics phenomena. Physics-based models may be useful for initial design as well as for operations, such as model-based control, virtual sensing, and process optimization.

In this detailed description, reference has been made to multiple embodiments and to the accompanying drawings in which are shown by way of illustration specific exemplary embodiments of the invention. These embodiments are described in sufficient detail to enable those skilled in the art to practice the invention, and it is to be understood that modifications to the various disclosed embodiments may be made by a skilled artisan.

Where methods and steps described above indicate certain events occurring in certain order, those of ordinary skill in the art will recognize that the ordering of certain steps may be modified and that such modifications are in accordance with the variations of the invention. Additionally, certain steps may be performed concurrently in a parallel process when possible, as well as performed sequentially.

All publications, patents, and patent applications cited in this specification are herein incorporated by reference in their entirety as if each publication, patent, or patent application were specifically and individually put forth herein.

The embodiments, variations, and figures described above should provide an indication of the utility and versatility of the present invention. Other embodiments that do not provide all of the features and advantages set forth herein may also be utilized, without departing from the spirit and scope of the present invention. Such modifications and variations are considered to be within the scope of the invention defined by the claims.

What is claimed is:

1. A pulsed-beam-deposition apparatus, said pulsed-beam-deposition apparatus comprising a plurality of elemental effusion cells positioned to deposit elemental materials onto a revolving substrate held by a substrate holder, wherein said revolving substrate and said plurality of elemental effusion cells are configured, without the use of sequential shuttering, to limit direct exposure of any point on said revolving substrate to a maximum of one elemental effusion cell at a time.

2. The pulsed-beam-deposition apparatus of claim 1, wherein each of said elemental effusion cells, in order to provide deposition uniformity, incorporates a beam-forming nozzle that emits a radially graded beam that compensates for differential tangential velocity of said revolving substrate.

3. The pulsed-beam-deposition apparatus of claim 1, wherein said pulsed-beam-deposition apparatus is disposed within a vacuum chamber.

4. The pulsed-beam-deposition apparatus of claim 1, wherein said revolving substrate is configured as a plurality of spatially separated substrates held by said substrate holder.

5. The pulsed-beam-deposition apparatus of claim 1, wherein said plurality of elemental effusion cells includes (i) one or more first elemental effusion cells containing a first element and (ii) one or more second elemental effusion cells containing a second element that is different than said first element.

6. The pulsed-beam-deposition apparatus of claim 5, wherein said plurality of elemental effusion cells further includes (iii) one or more third elemental effusion cells containing a third element.

7. The pulsed-beam-deposition apparatus of claim 1, wherein said plurality of elemental effusion cells is from 6 to 12 elemental effusion cells.

8. The pulsed-beam-deposition apparatus of claim 1, wherein for each of said elemental effusion cells, there is disposed a shutter that (i) when closed, blocks said elemental materials from depositing onto said revolving substrate; and (ii) when open, allows said elemental materials to deposit onto said revolving substrate.

9. The pulsed-beam-deposition apparatus of claim 1, wherein said pulsed-beam-deposition apparatus comprises effusion cell isolation shields disposed between each of said elemental effusion cells.

10. The pulsed-beam-deposition apparatus of claim 1, wherein said plurality of elemental effusion cells is isolated with a liquid nitrogen cryopanel.

11. A method of pulsed beam deposition, said method comprising:
(a) providing a revolving substrate held by a substrate holder;
(b) providing a plurality of elemental effusion cells each containing elemental materials, wherein said elemental effusion cells, when heated, collectively form elemental beams directed toward said revolving substrate; and
(c) depositing said elemental materials from said elemental beams onto said revolving substrate, wherein any point on said revolving substrate is directly exposed to a maximum of one elemental beam pulse at a time.

12. The method of claim 11, wherein said plurality of elemental effusion cells includes (i) one or more first elemental effusion cells containing a first element and (ii) one or more second elemental effusion cells containing a second element that is different than said first element.

13. The method of claim 11, wherein said revolving substrate is configured as a plurality of spatially separated substrates held by said substrate holder.

14. The method of claim 11, wherein said method does not employ co-deposition of distinct elemental materials at the same point and time on said revolving substrate.

15. The method of claim 11, wherein said method does not utilize sequential shuttering of said elemental effusion cells.

16. The method of claim 11, wherein said elemental beams are perpendicular to said revolving substrate for each of said elemental effusion cells.

17. The method of claim 11, wherein said method is conducted in a pressure range from about 10⁻⁴ Torr to about 10⁻¹² Torr.

18. The method of claim 11, wherein step (c) is characterized by a growth rate from about 0.1 μm/hour to about 10 μm/hour.

19. The method of claim 11, wherein step (c) is performed at a revolving speed from about 5 revolutions per minute to about 300 revolutions per minute.

20. The method of claim 11, wherein the direction of revolution of said revolving substrate is switched between clockwise and counterclockwise during step (c).

21. The method of claim 11, said method further comprising recovering one or more products each comprising deposited elemental materials.

22. A product produced by a process comprising the steps of:
(a) providing a revolving substrate held by a substrate holder;
(b) providing a plurality of elemental effusion cells each containing elemental materials, wherein said elemental effusion cells, when heated, collectively form elemental beams directed toward said revolving substrate;
(c) depositing said elemental materials from said elemental beams onto said revolving substrate, wherein any point on said revolving substrate is directly exposed to a maximum of one elemental beam pulse at a time; and
(d) recovering a product comprising said elemental materials deposited during step (c).

23. The product of claim 22, wherein said product is an epitaxial wafer.

24. The product of claim 23, wherein said epitaxial wafer has a diameter from about 1 inch to about 12 inches.

25. The product of claim 22, wherein said product contains one or more elements selected from the group consisting of B, Al, Ga, In, N, P, O, As, Sb, Bi, C, Si, Ge, Sn, Pb, Li, Na, K, Rb, Cs, Be, Mg, Ca, Sr, Ba, S, F, Cl, Br, I, Se, Te, Au, Pt, Cr, and Cd.
